(19) United States
(12) Patent Application Publication
(10) Pub. No.: US 2023/0320173 A1
(43) Pub. Date: Oct. 5, 2023

(54) DISPLAY DEVICE, LIGHT-EMITTING DEVICE AND ELECTRONIC APPARATUS

(71) Applicant: SONY SEMICONDUCTOR SOLUTIONS CORPORATION, KANAGAWA (JP)

(72) Inventor: TOMOKAZU OHCHI, KANAGAWA (JP)

(21) Appl. No.: 18/043,765

(22) PCT Filed: Sep. 8, 2021
(86) PCT No.: PCT/JP2021/033042

§ 371 Date: Mar. 2, 2023

(30) Foreign Application Priority Data
Sep. 11, 2020 (JP) 2020-152566

(51) Int. Cl. H10K 59/80

(52) U.S. Cl. CPC H10K 59/80518; H10K 59/80517; H10K 59/12

(57) ABSTRACT

Provided is a display device capable of reducing a pixel pitch while securing a light-emitting area. A display device includes an oxide layer including a plurality of first electrodes and an isolating portion that electrically isolates adjacent first electrodes; a second electrode facing one surface of the oxide layer; and an organic light-emitting layer provided between the oxide layer and the second electrode.

### TECHNICAL FIELD

The present disclosure relates to display devices, light-emitting devices, and electronic apparatuses.

### BACKGROUND ART

In recent years, organic EL (Electroluminescence) display devices (hereinafter simply referred to as “display devices”) have become widespread. As such display devices, those having various configurations have been proposed. In PTL 1, a display device including a plurality of first electrodes, a second electrode, an organic layer provided between the plurality of first electrodes and the second electrode, and a partition portion (insulating layer) provided between adjacent first electrodes is disclosed. In addition, it is disclosed that the plurality of first electrodes are formed by patterning a transparent conductive material layer such as an ITO layer using a well-known patterning technique such as lithography and etching.

### CITATION LIST

### Patent Literature

### [PTL 1]

WO 2020/105433

### SUMMARY

### Technical Problem

However, since a transparent conductive material such as ITO that constitutes the first electrode is a material that is difficult to etch (a so-called difficult-to-etch material), the display device described in PTL 1 has a problem that it is difficult to reduce a pixel pitch while securing a light-emitting area.

An object of the present disclosure is to provide a display device, a light-emitting device, and an electronic apparatus capable of reducing the pixel pitch while securing the light-emitting area.

### Solution to Problem

In order to solve the above-described problems, a first disclosure provides a display device including: an oxide layer including a plurality of first electrodes and an isolating portion that electrically isolates adjacent first electrodes; a second electrode facing one surface of the oxide layer; and an organic light-emitting layer provided between the oxide layer and the second electrode.

A second disclosure provides a light-emitting device including: an oxide layer including a plurality of first electrodes and an isolating portion that electrically isolates adjacent first electrodes; a second electrode facing the oxide layer; and an organic light-emitting layer provided between the oxide layer and the second electrode.

A third disclosure provides an electronic apparatus including the display device of the first disclosure or the light-emitting device of the second disclosure.

### BRIEF DESCRIPTION OF DRAWINGS

FIG. 1 is a schematic diagram showing an example of the overall configuration of a display device according to a first embodiment of the present disclosure.

FIG. 2 is a cross-sectional view showing an example of the configuration of the display device according to the first embodiment of the present disclosure.

FIG. 3 is a plan view showing an example of the configuration of an oxide layer.

FIGS. 4A, 4B, 4C, and 4D are process diagrams for explaining an example of a method for manufacturing the display device according to the first embodiment of the present disclosure.

FIGS. 5A, 5B, and 5C are process diagrams for explaining an example of the method for manufacturing the display device according to the first embodiment of the present disclosure.

FIG. 6 is a cross-sectional view showing an example of the configuration of the display device according to a second embodiment of the present disclosure.

FIGS. 7A, 7B, and 7C are process diagrams for explaining an example of a method for manufacturing a display device according to the second embodiment of the present disclosure.

FIGS. 8A and 8B are process diagrams for explaining an example of a method for manufacturing a display device according to the second embodiment of the present disclosure.

FIG. 9 is a cross-sectional view showing an example configuration of a display device according to a third embodiment of the present disclosure.

FIGS. 10A, 10B, and 10C are process diagrams for explaining an example of a method for manufacturing a display device according to the third embodiment of the present disclosure.

FIGS. 11A, 11B, and 11C are process diagrams for explaining an example of a method for manufacturing a display device according to the third embodiment of the present disclosure.

FIG. 12 is a cross-sectional view showing an example of the configuration of a display device according to a modification example.

FIG. 13 is a plan view showing an example of the schematic configuration of the module.

FIG. 14A is a front view showing an example of the appearance of a digital still camera. FIG. 14B is a rear view showing an example of the appearance of the digital still camera.

FIG. 15 is a perspective view of an example of the appearance of a head-mounted display.

FIG. 16 is a perspective view showing an example of the appearance of a television device.

### DESCRIPTION OF EMBODIMENTS

An embodiment of the present disclosure will be described in the following order. In addition, in all drawings of the following embodiments, the same or corresponding parts are denoted by the same reference numerals.
1 First Embodiment
1.1 Configuration of display device
1.2 Manufacturing method of display device
1.3 Operation and effect
2 Second Embodiment
2.1 Configuration of display device
2.2 Manufacturing method of display device
2.3 Operation and effect
3 Third Embodiment
3.1 Configuration of display device
3.2 Manufacturing method of display device
3.3 Operation and effect
4 Modification Example
5 Application Example

### 1 FIRST EMBODIMENT

### 1.1 Configuration of Display Device

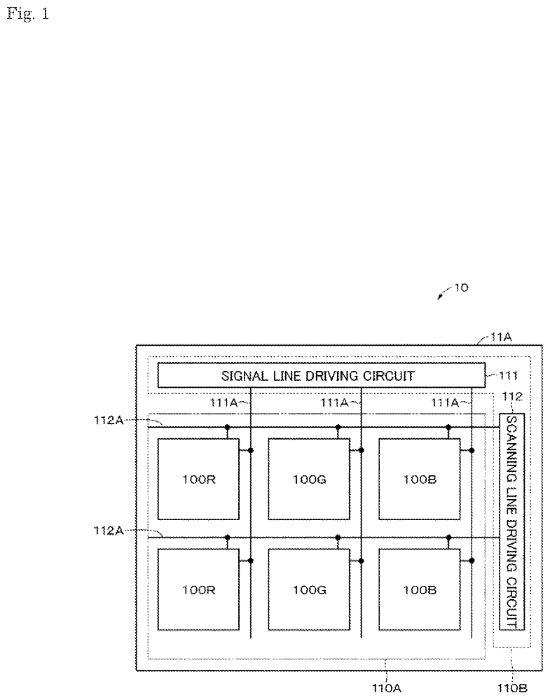

FIG. 1 is a schematic diagram showing an example of the overall configuration of a display device 10 according to the first embodiment of the present disclosure. The display device 10 has a display region 110A and a peripheral region 110B provided around the periphery of the display region 110A. In the display region 110A, a plurality of sub-pixels 100R, 100G, and 100B are two-dimensionally arranged in a predetermined arrangement pattern such as a matrix. The pixel pitch of the sub-pixels 100 is preferably 10 μm or less from the viewpoint of achieving high definition of the display device 10.

The sub-pixel 100R displays red, the sub-pixel 100G displays green, and the sub-pixel 100B displays blue. In the following description, the sub-pixels 100R, 100G, and 100B are referred to as sub-pixels 100 when the sub-pixels are not particularly distinguished. A combination of adjacent sub-pixels 100R, 100G, and 100B constitutes one pixel. FIG. 1 shows an example in which a combination of three sub-pixels 100R, 100G, and 100B arranged in the row direction (horizontal direction) forms one pixel.

A signal line driving circuit 111 and a scanning line driving circuit 112, which are drivers for video display, are provided in the peripheral region 110B. The signal line driving circuit 111 supplies a signal voltage of a video signal corresponding to luminance information supplied from a signal supply source (not shown) to the selected sub-pixel 100 via a signal line 111A. The scanning line driving circuit 112 is configured by a shift register or the like that sequentially shifts (transfers) start pulses in synchronization with input clock pulses. The scanning line driving circuit 112 scans the sub-pixels 100 row by row when writing video signals to the sub-pixels 100, and sequentially supplies scanning signals to the scanning lines 112A.

The display device 10 is an example of a light-emitting device. The display device 10 may be a microdisplay. The display device 10 is suitable for use as a display device for VR (Virtual Reality), MR (Mixed Reality) or AR (Augmented Reality), an electronic view finder (EVF), a small projector, or the like.

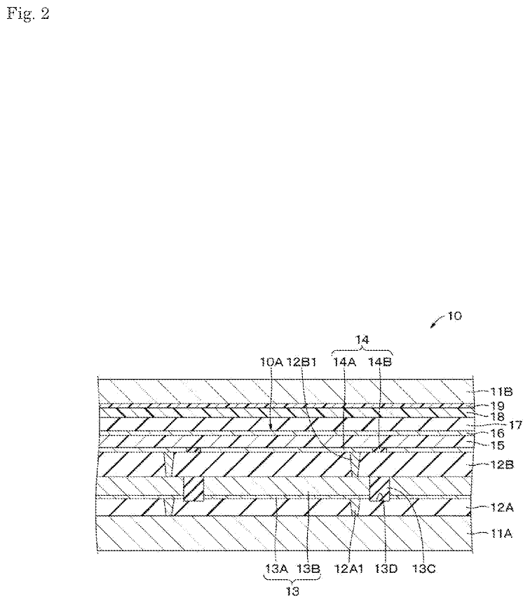

FIG. 2 is a cross-sectional view showing an example of the configuration of the display device 10 according to the first embodiment of the present disclosure. The display device 10 includes a driving substrate 11A, a first insulating layer 12A, a plurality of reflective layers 13, an insulating portion 13C, a second insulating layer 12B, an oxide layer 14, an organic layer 15, a second electrode 16, a protective layer 17, a color filter 18, a filling resin layer 19, and a counter substrate 11B. The oxide layer 14 includes a plurality of first electrodes 14A and an isolating portion 14B. The reflective layer 13 and the second electrode 16 may form a resonator structure.

The display device 10 is a top emission type display device. The counter substrate 11B side is the top side (display surface side), and the driving substrate 11A side is the bottom side. In the following description, in each layer constituting the display device 10, the top surface of the display device 10 is referred to as a first surface, and the bottom surface of the display device 10 is referred to as a second surface.

The display device 10 includes a plurality of light-emitting elements 10A. The light-emitting element 10A is composed of a first electrode 14A, an organic layer 15 and a second electrode 16. The light-emitting element 10A is a white OLED or white Micro-OLED (MOLED). As a method of colorization in the display device 10, a method using a white OLED and the color filter 18 is used. However, the colorization method is not limited to this, and an RGB coloring method or the like may be used.

### Driving Substrate

The driving substrate 11A is a so-called backplane, and drives the plurality of light-emitting elements 10A. A driving circuit and a power supply circuit (both not shown) are provided on the first surface of the driving substrate 11A. The driving circuit includes a sampling transistor and a driving transistor that control driving of the plurality of light-emitting elements 10A. The power supply circuit supplies electric power to the plurality of light-emitting elements 10A.

The driving substrate 11A may be made of, for example, glass or resin having low moisture and oxygen permeability, or may be made of a semiconductor that facilitates formation of transistors and the like. Specifically, the driving substrate 11A may be a glass substrate, a semiconductor substrate, a resin substrate, or the like. Glass substrates include, for example, high strain-point glass, soda glass, borosilicate glass, forsterite, lead glass, or quartz glass. Semiconductor substrates include, for example, amorphous silicon, polycrystalline silicon, monocrystalline silicon, or the like. The resin substrate contains, for example, at least one selected from the group consisting of polymethyl methacrylate, polyvinyl alcohol, polyvinyl phenol, polyethersulfone, polyimide, polycarbonate, polyethylene terephthalate and polyethylene naphthalate.

### First Insulating Layer

The first insulating layer 12A is provided on the first surface of the driving substrate 11A and covers the driving circuit, the power supply circuit, and the like. The first insulating layer 12A has a plurality of contact plugs 12A1. Each contact plug 12A1 connects the light-emitting element 10A and the reflective layer 13. The first insulating layer 12A may further include a plurality of wirings (not shown).

The first insulating layer 12A contains, for example, an organic material or an inorganic material. The organic material includes, for example, at least one selected from the group consisting of polyimide, acrylic resin, and the like. The inorganic material includes, for example, at least one selected from the group consisting of silicon oxide, silicon nitride, silicon oxynitride and aluminum oxide.

### Second Insulating Layer

The second insulating layer 12B is provided on the first surfaces of the plurality of reflective layers 13 and the insulating portion 13C to cover the plurality of reflective layers 13. That is, the second insulating layer 12B is provided between the oxide layer 14 and the plurality of reflective layers 13. The second insulating layer 12B has a plurality of contact plugs 12B1. Each contact plug 12B1 connects the light-emitting element 10A and the reflective layer 13. As a constituent material of the second insulating layer 12B, the same material as that of the above-described first insulating layer 12A can be exemplified.

### Reflective Layer

A plurality of reflective layers 13 are provided on the first surface of the first insulating layer 12A. The plurality of reflective layers 13 are provided at positions corresponding to the plurality of sub-pixels 100. The plurality of reflective layers 13 face the second surface (the other surface) of the oxide layer 14 with the second insulating layer 12B interposed therebetween. The plurality of reflective layers 13 face the plurality of first electrodes 14A, respectively. The reflective layer 13 reflects light emitted from the organic layer 15. The reflective layer 13 includes a first metal layer 13A and a second metal layer 13B. However, the first metal layer 13A is provided as necessary, and may not be provided. A groove 13D is provided between adjacent reflective layers 13.

### First Metal Layer

The first metal layer 13A is provided on the first surface of the first insulating layer 12A. The first metal layer 13A is an underlying layer for improving the crystal orientation of the second metal layer 13B when forming the second metal layer 13B. By improving the crystal orientation of the second metal layer 13B, the uneven shape of the surface (first surface) of the second metal layer 13B can be reduced. The second surface of the first metal layer 13A is connected to a contact plug 12A1 provided in the first insulating layer 12A.

The first metal layer 13A contains, for example, at least one metal element selected from the group consisting of titanium (Ti) and tantalum (Ta). The first metal layer 13A may contain the at least one metal element as a constituent element of an alloy.

### Second Metal Layer

The second metal layer 13B is provided on the first surface of the first metal layer 13A. The second metal layer 13B functions as a reflective layer that reflects light emitted from the organic layer 15. The first surface of the second metal layer 13B is connected to a contact plug 12B1 provided in the second insulating layer 12B.

The second metal layer 13B contains at least one metal element selected from the group consisting of, for example, aluminum (Al), silver (Ag), chromium (Cr), gold (Au), platinum (Pt), nickel (Ni), copper (Cu), molybdenum (Mo), magnesium (Mg), iron (Fe) and tungsten (W). The second metal layer 13B may contain the at least one metal element as a constituent element of an alloy. Specific examples of alloys include aluminum alloys and silver alloys. Specific examples of aluminum alloys include AlNd and AlCu. From the viewpoint of improving the reflectance, the second metal layer 13B preferably contains at least one metal element selected from the group consisting of aluminum (Al) and silver (Ag) among the above metal elements.

### Insulating Portion

The insulating portion 13C is provided in the groove 13D between the adjacent reflective layers 13 and fills the groove 13D. The insulating portion 13C electrically isolates the adjacent reflective layers 13 and spatially separates them. As a constituent material of the insulating portion 13C, the same material as that of the first insulating layer 12A can be exemplified.

### Oxide Layer

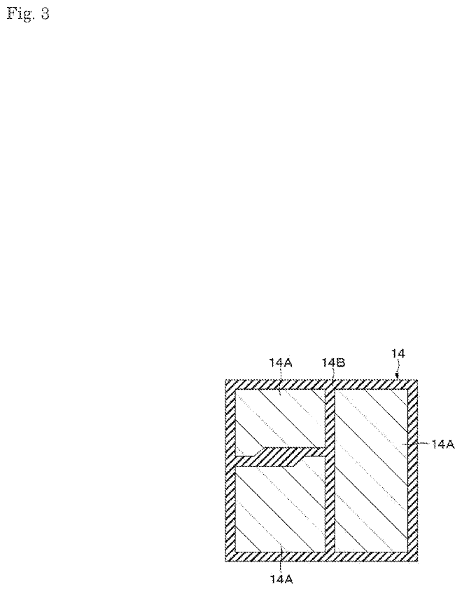

FIG. 3 is a plan view showing an example of the configuration of the oxide layer 14. The oxide layer 14 is provided on the first surface of the second insulating layer 12B. The oxide layer 14 includes a metal oxide. The metal oxide contains, for example, at least one selected from the group consisting of oxides containing indium, oxides containing tin, and oxides containing zinc. The oxide layer 14 includes the plurality of first electrodes 14A and the isolating portion 14B, as described above.

### First Electrode

The plurality of first electrodes 14A are two-dimensionally arranged in a predetermined arrangement pattern such as a matrix on the first surface of the second insulating layer 12B. Each first electrode 14A is provided in a portion corresponding to the sub-pixel 100. The first electrode 14A is the anode. When a voltage is applied between the first electrode 14A and the second electrode 16, holes are injected into the organic layer 15 from the first electrode 14A. The first electrode 14A is a transparent electrode and transmits light emitted from the organic layer 15. The second surface of the first electrode 14A is connected to a contact plug 12B1 provided in the second insulating layer 12B. The first electrode 14A is preferably made of a material having a high work function and a high transmittance in order to increase the luminous efficiency.

The first electrode 14A includes a first oxide. The first oxide is a transparent conductive oxide (TCO). The transparent conductive oxides include at least one selected from the group consisting of, for example, transparent conductive oxides containing indium (hereinafter referred to as “indium-based transparent conductive oxides”), transparent conductive oxides containing tin (hereinafter referred to as “tin-based transparent conductive oxides”) and transparent conductive oxides containing zinc (hereinafter referred to as “zinc-based transparent conductive oxides”).

Indium-based transparent conductive oxides include, for example, indium tin oxide (ITO), indium zinc oxide (IZO), indium gallium oxide (IGO) or indium gallium zinc oxide (IGZO) fluorine-doped indium oxide (IFO). Among these transparent conductive oxides, indium tin oxide (ITO) is particularly preferred. This is because indium tin oxide (ITO) has a particularly low hole injection barrier to the organic layer 15 in terms of work function, so that the driving voltage of the display device 10 can be particularly reduced. Tin-based transparent conductive oxides include, for example, tin oxide, antimony-doped tin oxide (ATO), or fluorine-doped tin oxide (PTO). Zinc-based transparent conductive oxides include, for example, zinc oxide, aluminum-doped zinc oxide (AZO), boron-doped zinc oxide, or gallium-doped zinc oxide (GZO).

### Isolating Portion

The isolating portion 14B is provided between the first electrodes 14A adjacent in the in-plane direction. The isolating portion 14B surrounds the entire circumference of the first electrode 14A. The isolating portion 14B has, for example, a lattice shape. Each isolating portion 14B electrically isolates the first electrodes 14A adjacent in the in-plane direction. In the present specification, the in-plane direction means a direction along the first surface (display surface) of the display device 10 or the first surface of the driving substrate 11A. The electrical resistance of the isolating portion 14B is higher than that of the first electrode 14A. Preferably, the isolating portion 14B is an insulating portion.

The isolating portion 14B includes a second oxide that is an insulating material. The second oxide is an insulating oxide. The insulating oxide includes at least one selected from the group consisting of, for example, an insulating oxide containing indium (hereinafter referred to as “indium-based insulating oxide”), an insulating oxide containing tin (hereinafter referred to as “tin-based insulating oxide”), and insulating oxides containing zinc (hereinafter referred to as “zinc-based insulating oxides”). The second oxide may be an insulating oxide obtained by adding impurities (ions) to the first oxide. Impurities, when added, can change the transparent conductive oxide into an insulating oxide. Specifically, for example, impurities include at least one selected from the group consisting of oxygen (O), sulfur (S) and nitrogen (N).

The first oxide contained in the first electrode 14A and the second oxide contained in the isolating portion 14B may have the same constituent material (constituent element), and the first oxide and the second oxide may have different composition ratios. Alternatively, part of the constituent materials of the first oxide contained in the first electrode 14A and the second oxide contained in the isolating portion 14B may be the same, and the rest may be different. In order to make the electrical resistance of the first electrode 14A lower than the electrical resistance of the isolating portion 14B, the crystallinity of the first electrode 14A is preferably higher than the crystallinity of the isolating portion 14B. The first electrode 14A and the isolating portion 14B may have different optical characteristics such as transmittance.

### Second Electrode

The second electrode 16 corresponds to the first surface of the oxide layer 14 with the organic layer 15 interposed therebetween. The second electrode 16 is provided as a common electrode for all sub-pixels 100 within the display region 110A. The second electrode 16 is the cathode. When a voltage is applied between the first electrode 14A and the second electrode 16, electrons are injected from the second electrode 16 into the organic layer 15. The second electrode 16 is a transparent electrode that is transparent to light generated in the organic layer 15. Here, the transparent electrode includes a semi-transmissive reflective layer. The second electrode 16 is preferably made of a material having as high transmittance as possible and a small work function, in order to increase the luminous efficiency.

The second electrode 16 is composed of, for example, at least one layer of a metal layer and a transparent electrode. More specifically, the second electrode 16 is composed of a single layer film of a metal layer or a transparent electrode, or a laminated film of a metal layer and a transparent electrode. When the second electrode 16 is composed of a laminated film, the metal layer may be provided on the organic layer 15 side, and the transparent electrode may be provided on the organic layer 15 side. However, from the viewpoint of placing a layer with a low work function adjacent to the organic layer 15, the metal layer is preferably provided on the organic layer 15 side.

The metal layer contains, for example, at least one metal element selected from the group consisting of magnesium (Mg), aluminum (Al), silver (Ag), calcium (Ca) and sodium (Na). The metal layer may contain the at least one metal element as a constituent element of an alloy. Specific examples of alloys include MgAg alloys, MgAl alloys, AlLi alloys, and the like. A transparent electrode contains a transparent conductive oxide. Examples of the transparent conductive oxide include the same materials as those of the first electrode 14A described above.

### Organic Layer

The organic layer 15 is provided between the oxide layer 14 and the second electrode 16. The organic layer 15 is provided as an organic layer common to all sub-pixels 100 within the display region 110A. The organic layer 15 is configured to emit white light.

The organic layer 15 has a configuration in which a hole injection layer, a hole transport layer, a light-emitting layer, and an electron transport layer are laminated in this order from the oxide layer 14 toward the second electrode 16. The configuration of the organic layer 15 is not limited to this, and layers other than the light-emitting layer are provided as necessary.

The hole injection layer is a buffer layer for increasing the efficiency of hole injection into the light-emitting layer and suppressing leakage. The hole transport layer is for increasing the efficiency of transporting holes to the light-emitting layer. In the light-emitting layer, recombination of electrons and holes occurs when an electric field is applied to generate light. The light-emitting layer is an organic light-emitting layer containing an organic light-emitting material. The electron transport layer is for enhancing the efficiency of transporting electrons to the light-emitting layer. An electron injection layer may be provided between the electron transport layer and the second electrode 16. This electron injection layer is for enhancing the electron injection efficiency.

### Protective Layer

The protective layer 17 is provided on the first surface of the second electrode 16 and covers the plurality of light-emitting elements 10A. The protective layer 17 shields the light-emitting element 10A from the outside air, and suppresses the intrusion of moisture from the external environment into the light-emitting element 10A. Moreover, when the second electrode 16 is composed of a metal layer, the protective layer 17 may have a function of suppressing oxidation of this metal layer.

The protective layer 17 contains, for example, an inorganic material with low hygroscopicity. The inorganic material includes, for example, at least one of silicon oxide (SiO), silicon nitride (SiN), silicon oxynitride (SiNO), titanium oxide (TiO) and aluminum oxide (AlO). The protective layer 17 may have a single layer structure or a multilayer structure. In the case of a multilayer structure, internal stress in the protective layer 17 can be relaxed. The protective layer 17 may be made of polymer resin. The polymer resin includes at least one selected from the group consisting of thermosetting resins, ultraviolet curing resins, and the like.

### Color Filter

The color filter 18 is provided on the first surface of the protective layer 17. The color filter 18 is, for example, an on-chip color filter (OCCF). The color filter 18 includes, for example, a red filter, a green filter and a blue filter. The red filter, green filter, and blue filter are provided to face the light-emitting element 10A for the red sub-pixel 100R, the light-emitting element 10A for the green sub-pixel 100G, and the light-emitting element 10A for the blue sub-pixel 100B, respectively. The sub-pixels 100R, 100G, and 100B are thus configured.

White light emitted from each light-emitting element 10A in the sub-pixels 100R, 100G, and 100B is transmitted through the red, green, and blue filters, respectively, so that the red, green, and blue lights are emitted from the display surface. A light shielding layer (not shown) may be provided in the region between the color filters of each color, that is, between the sub-pixels. The color filters 18 are not limited to on-chip color filters, and may be provided on one main surface of the counter substrate 11B.

### Filling Resin Layer

The filling resin layer 19 is provided between the color filter 18 and the counter substrate 11B. The filling resin layer 19 functions as an adhesive layer that bonds the color filter 18 and the counter substrate 11B. The filling resin layer 19 contains, for example, at least one selected from the group consisting of thermosetting resins, ultraviolet curing resins, and the like.

### Counter Substrate

The counter substrate 11B is provided to face the driving substrate 11A. More specifically, the counter substrate 11B is provided such that the second surface of the counter substrate 11B faces the first surface of the driving substrate 11A. The counter substrate 11B and the filling resin layer 19 seal the light-emitting element 10A, the color filter 18, and the like. The counter substrate 11B is made of a material such as glass that is transparent to each color light emitted from the color filter 18.

### 1.2 Manufacturing Method of Display Device

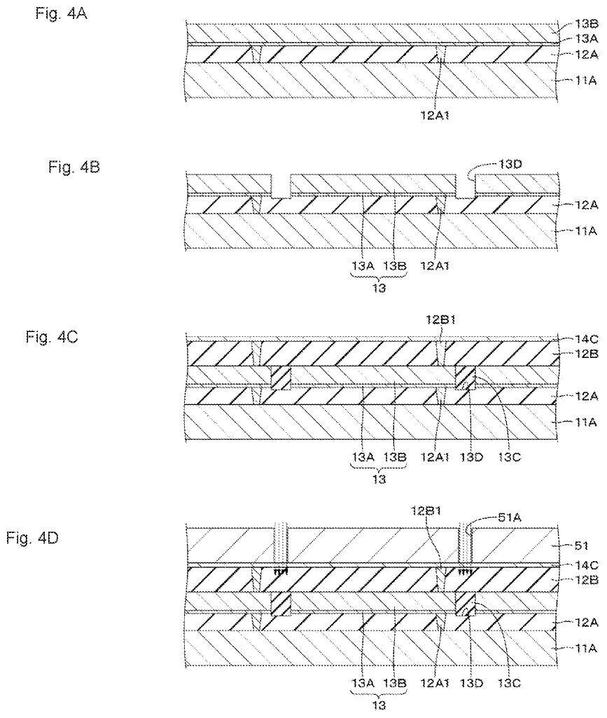

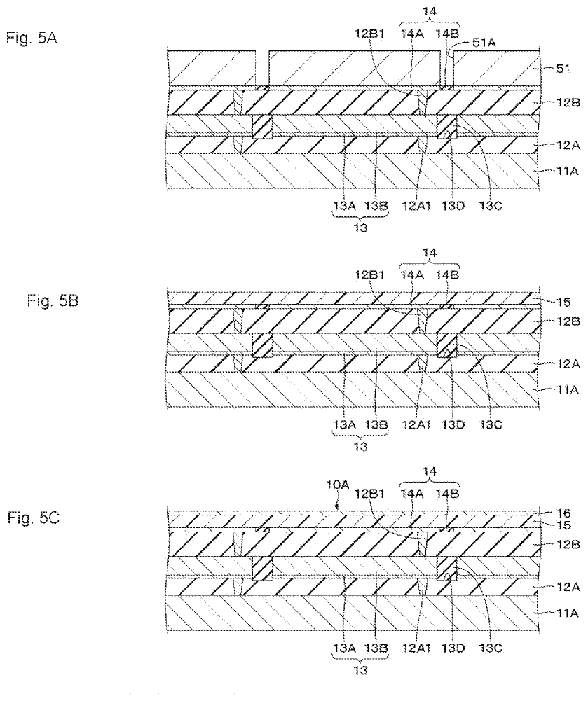

An example of a method for manufacturing the display device 10 according to the first embodiment of the present disclosure will be described below with reference to FIGS. 4A to 4D and FIGS. 5A to 5C.

First, a driving circuit, a power supply circuit, and the like are formed on the first surface of the driving substrate 11A using, for example, thin film formation technology, photolithography technology, and etching technology. Next, a first insulating layer 12A is formed on the first surface of the driving substrate 11A so as to cover the driving circuit, the power supply circuit, and the like by, for example, a CVD (Chemical Vapor Deposition) method. At this time, a plurality of contact plugs 12A1 are formed in the first insulating layer 12A.

Next, the first metal layer 13A is formed on the first surface of the first insulating layer 12A by, for example, sputtering. Subsequently, the second metal layer 13B is formed on the first surface of the first metal layer 13A by, for example, sputtering (see FIG. 4A). Next, after forming a resist mask having a predetermined pattern on the first surface of the second metal layer 13B, the first metal layer 13A and the second metal layer 13B are dry-etched through the resist mask. In this way, a plurality of reflective layers 13 separated by grooves 13D are formed on the first surface of the first insulating layer 12A (see FIG. 4B).

Next, an insulating layer is formed in the grooves 13D between the adjacent reflective layers 13 and on the first surfaces of the plurality of reflective layers 13 by, for example, the CVD method. Next, the insulating layer formed on the first surface of each reflective layer 13 is removed by, for example, an etch-back method or a CMP (Chemical Mechanical Polishing) method. As a result, an insulating portion 13C is formed in the groove 13D between the adjacent reflective layers 13. Next, the second insulating layer 12B is formed on the first surfaces of the plurality of reflective layers 13 and the insulating portions 13C by, for example, CVD. At this time, a plurality of contact plugs 12B1 are formed in the second insulating layer 12B.

Next, a transparent conductive oxide layer 14C is formed on the first surface of the second insulating layer 12B by sputtering, for example (see FIG. 4C). Next, a resist mask 51 having a predetermined pattern is formed on the first surface of the transparent conductive oxide layer 14C (see FIG. 4D). As the resist mask 51, one having openings 51A in portions corresponding to the positions between adjacent sub-pixels 100 is used. Next, ions are implanted into the transparent conductive oxide layer 14C through the openings 51A of the resist mask 51. A portion of the transparent conductive oxide layer 14C into which ions are implanted has a high resistance. In this way, an oxide layer 14 having the plurality of first electrodes 14A and the isolating portion 14B is formed (see FIG. 5A). At least one selected from the group consisting of oxygen (O), sulfur (S), nitrogen (N) and the like is used as the ions to be implanted. Next, the resist mask 51 is removed from the first surface of the oxide layer 14.

Next, the organic layer 15 is formed by laminating a hole injection layer, a hole transport layer, a light-emitting layer, and an electron transport layer in this order on the first surface of the oxide layer 14 by vapor deposition, for example (see FIG. 5B). Next, the second electrode 16 is formed on the first surface of the organic layer 15 by vapor deposition or sputtering, for example. In this way, a plurality of light-emitting elements 10A are formed on the first surface of the second insulating layer 12B (see FIG. 5C).

Next, after forming a protective layer 17 on the first surface of the second electrode 16 by, for example, CVD or vapor deposition, a color filter 18 is formed on the first surface of the protective layer 17 by, for example, photolithography. A planarization layer may be formed above, below, or both above and below the color filter 18 in order to planarize the step of the protective layer 17 and the step due to the film thickness difference of the color filter 18 itself. Next, after covering the color filter 18 with the filling resin layer 19 using, for example, the ODF (One Drop Fill) method, the counter substrate 11B is placed on the filling resin layer 19. Next, for example, by applying heat to the filling resin layer 19 or irradiating the filling resin layer 19 with ultraviolet rays to harden the filling resin layer 19, the driving substrate 11A and the counter substrate 11B are bonded together with the filling resin layer 19 interposed therebetween. In this way, the display device 10 is sealed. As described above, the display device 10 shown in FIGS. 1 and 2 is obtained.

### 1.3 Operation and Effect

As described above, the display device 10 according to the first embodiment includes the oxide layer 14, and the oxide layer 14 includes the plurality of first electrodes 14A and the isolating portion 14B that electrically isolates adjacent first electrodes 14A. The isolating portion 14B can be formed by implanting ions into the transparent conductive oxide layer 14C through a resist mask. Therefore, the adjacent first electrodes 14A can be electrically isolated without etching the transparent conductive oxide, which is a difficult-to-etch material. Therefore, the pixel pitch can be reduce (for example, reduced to 10 μm or less) while securing the light-emitting area.

In a conventional display device, a partition portion (insulating layer) is provided between adjacent first electrodes, whereas in the display device 10 according to the first embodiment, the isolating portion 14B is provided instead of the partition portion (insulating layer). Therefore, in the display device 10 according to the first embodiment, the sub-pixels 100 can be reduced. Moreover, it is possible to eliminate deterioration of characteristics (for example, edge leak, burn-in, and heat resistance) caused by the partition wall.

Since the transparent conductive oxide is a difficult-to-etch material, if the first electrodes are manufactured by etching the transparent conductive oxide layer to the size of the resist resolution limit, a short circuit may occur between adjacent first electrodes. Therefore, in the conventional display device, it was necessary to etch the transparent conductive oxide layer in a size larger than the resist resolution limit. In contrast, in the display device 10 according to the first embodiment, the adjacent first electrodes 14A can be isolated by implanting ions into the transparent conductive oxide layer 14C through the resist mask. Therefore, the transparent conductive oxide layer 14C can be processed with the size of resist resolution limit. That is, it is possible to form the isolating portion 14B having the size of the resist resolution limit.

### 2 SECOND EMBODIMENT

### 2.1 Configuration of Display Device

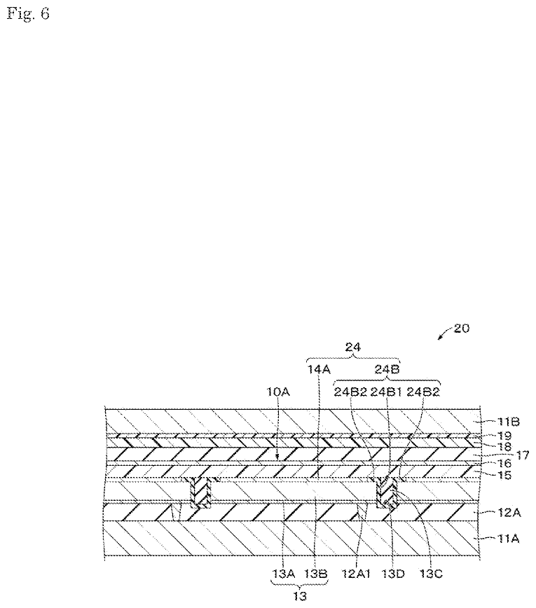

FIG. 6 is a cross-sectional view showing an example of the configuration of a display device 20 according to a second embodiment of the present disclosure. The display device 20 includes an oxide layer 24 instead of the oxide layer 14 (see FIG. 2). Each of the plurality of reflective layers 13 is adjacent to the second surface of the plurality of first electrodes 14A. In the second embodiment, the same parts as those in the first embodiment are denoted by the same reference numerals, and descriptions thereof will be omitted.

### Oxide Layer

The oxide layer 24 is provided on the first surfaces of the plurality of reflective layers 13 so as to follow the shape of the grooves 13D. The oxide layer 24 includes an isolating portion 24B instead of the isolating portion 14B (see FIG. 2).

### Isolating Portion

The isolating portion 24B has a recess 24B1 and a covering portion 24B2. However, the configuration of the isolating portion 24B is not limited to this, and the isolating portion 24B may not have the covering portion 24B2. The recess 24B1 has a concave shape with respect to the first surface of the first electrode 14A. In the second embodiment, the first surface (main surface) of the reflective layer 13 faces the organic layer 15 with the first electrode 14A interposed therebetween. The recess 24B1 is provided in the groove 13D between the adjacent reflective layers 13. The recess 24B1 may follow the shape of the groove 13D. The insulating portion 13C is provided in the recess 24B1.

The covering portion 24B2 covers the peripheral portion of the first surface (main surface) of the reflective layer 13. Here, the peripheral portion of the first surface of the reflective layer 13 refers to a region having a predetermined width toward the inner side from the peripheral edge of the first surface of the reflective layer 13. If the isolating portion 24B has the covering portion 24B2, the insulation between the sub-pixels 100 can be further improved. From the viewpoint of improving insulation between the sub-pixels 100, the groove 13D preferably has a depth equal to or greater than the thickness of the reflective layer 13.

The isolating portion 24B is the same as the isolating portion 14B in the first embodiment except for the points described above.

### 2.2 Manufacturing Method of Display Device

An example of a method for manufacturing the display device 20 according to the second embodiment of the present disclosure will be described below with reference to FIGS. 4B, 7A to 7C, 8A, and 8B.

First, the steps up to the patterning of the first metal layer 13A and the second metal layer 13B are performed in the same manner as in the manufacturing method of the display device 10 according to the first embodiment. In this way, a plurality of reflective layers 13 separated by the grooves 13D are formed on the first surface of the first insulating layer 12A (see FIG. 4B).

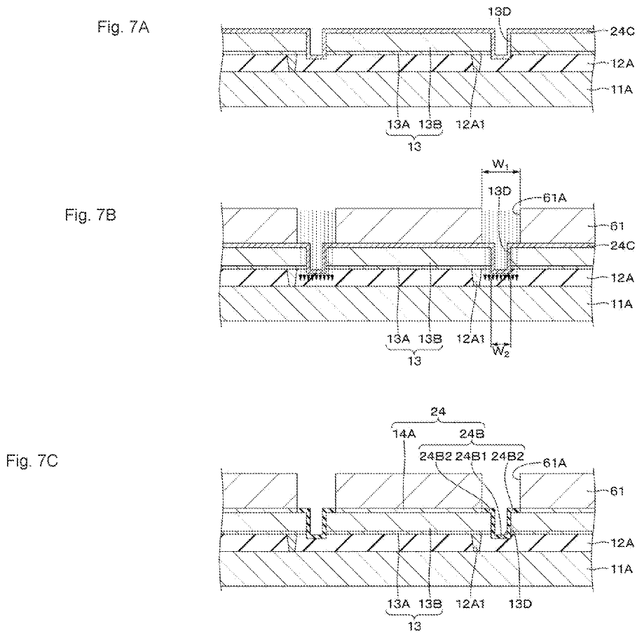

Next, a transparent conductive oxide layer 24C is formed on the first surfaces of the plurality of reflective layers 13 by, for example, a sputtering method so as to follow the shape of the grooves 13D between the adjacent reflective layers 13 (see FIG. 7A). Next, a resist mask 61 having a predetermined pattern is formed on the first surface of the transparent conductive oxide layer 24C (see FIG. 7B). As the resist mask 61, one having an opening 61A in the groove 13D is used. The width W1 of the opening 61A may be the same as the width W2 of the groove 13D, or may be wider than the width W2 of the groove 13D. If the width W1 of the opening 61A is wider than the width W2 of the groove 13D, the isolating portion 24B having the covering portion 24B2 is formed in the subsequent ion implantation step. On the other hand, when the width W1 of the opening 61A is equal to the width W2 of the groove 13D, the isolating portion 24B without the covering portion 24B2 is formed in the subsequent ion implantation step.

Next, ions are implanted into the transparent conductive oxide layer 24C through the openings 61A of the resist mask (see FIG. 7B). A portion of the transparent conductive oxide layer 14C into which ions are implanted has a high resistance. In this way, an oxide layer 24 having a plurality of first electrodes 14A and an isolating portion 24B is formed (see FIG. 7C). At least one selected from the group consisting of oxygen (O), sulfur (S), nitrogen (N) and the like is used as the ions to be implanted. Next, the resist mask 61 is removed from the first surface of the oxide layer 24.

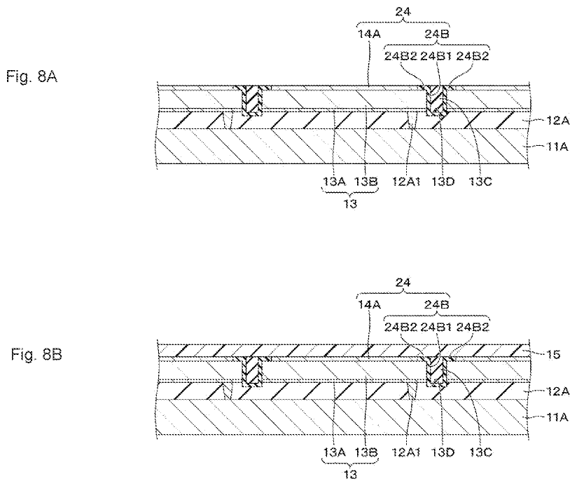

Next, an insulating layer is formed in the recesses 24B1 between the adjacent reflective layers 13 and on the first surfaces of the plurality of reflective layers 13 by, for example, the CVD method. Next, the insulating layer formed on the first surface of each reflective layer 13 is removed by, for example, an etch-back method or a CMP method. As a result, the insulating portion 13C is formed in the recess 24B1 between the adjacent reflective layers 13 (see FIG. 8A). Next, the organic layer 15 is formed by laminating a hole injection layer, a hole transport layer, a light-emitting layer, and an electron transport layer in this order on the first surface of the oxide layer 24 by vapor deposition, for example (see FIG. 8B).

Subsequent steps are performed in the same manner as in the manufacturing method of the display device 10 of the first embodiment. In this way, the display device 20 shown in FIG. 6 is obtained.

### Operation and Effect

As described above, the display device 20 according to the second embodiment includes the oxide layer 24, and the oxide layer 24 includes the plurality of first electrodes 14A and the isolating portion 24B. Therefore, the same effect as the display device 10 according to the first embodiment can be obtained.

The isolating portion 24B has the recess 24B1 and the covering portion 24B2. The recess 24B1 is provided in the groove 13D, and the covering portion 24B2 covers the peripheral portion of the first surface of the reflective layer 13. In this way, it is possible to increase the resistance of the recess 24B1 and its surroundings.

Since the dry etching process of the transparent conductive oxide becomes unnecessary, it is possible to reduce the etching depth of the underlying layer. Therefore, the step between the sub-pixels 100 can be reduced, and leakage between the first electrode 14A and the second electrode 16 via the organic layer 15 can be suppressed.

### 3 THIRD EMBODIMENT

### 3.1 Configuration of Display Device

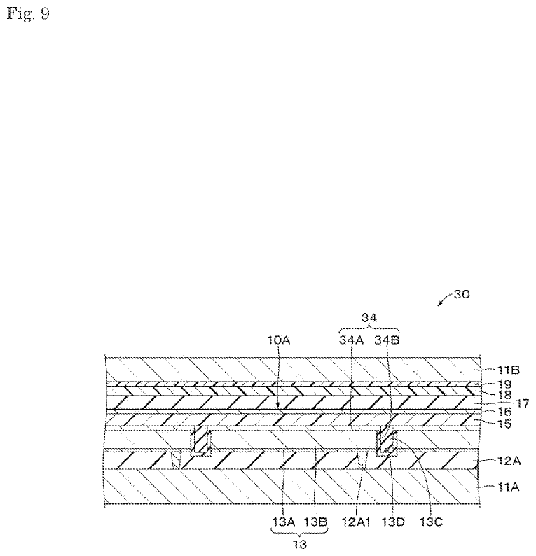

FIG. 9 is a cross-sectional view showing an example of the configuration of a display device 30 according to a third embodiment of the present disclosure. The display device 30 includes an oxide layer 34 instead of the oxide layer 24 (see FIG. 2). In the third embodiment, the same parts as those in the second embodiment are denoted by the same reference numerals, and descriptions thereof will be omitted.

### Oxide Layer

The oxide layer 34 is provided on the first surfaces of the plurality of reflective layers 13 so as to follow the shape of the grooves 13D. The oxide layer 34 includes a first electrode 34A and an isolating portion 34B.

The first electrode 34A contains a third oxide. The third oxide may be a transparent conductive oxide obtained by adding a first impurity (first ion) and a second impurity (second ion) to the first oxide. The first impurity, when added, can increase the resistance of the transparent conductive oxide and change the transparent conductive oxide into an insulating oxide. Specifically, for example, the first impurity contains at least one selected from the group consisting of oxygen (O), sulfur (S) and nitrogen (N). The second impurity, when added, can lower the resistance of the insulating oxide and change the insulating oxide into a transparent conductive oxide. Specifically, for example, the second impurity contains at least one selected from the group consisting of hydrogen (H), lithium (Li), magnesium (Mg) and cesium (Cs). The first electrode 34A is the same as the first electrode 14A in the first embodiment except for the points described above.

The isolating portion 34B is a recess. The recess is similar to the recess 24B1 of the isolating portion 24B in the second embodiment.

### 3.2 Manufacturing Method of Display Device

An example of a method for manufacturing the display device 30 according to the third embodiment of the present disclosure will be described below with reference to FIGS. 7A, 10A to 10C, and 11A to 11C.

First, the steps up to the formation of the transparent conductive oxide layer 24C are performed in the same manner as in the method of manufacturing the display device 20 according to the second embodiment. In this way, a transparent conductive oxide layer 24C is formed on the first surfaces of the plurality of reflective layers 13 so as to follow the shape of the grooves 13D between the adjacent reflective layers 13 (see FIG. 7A).

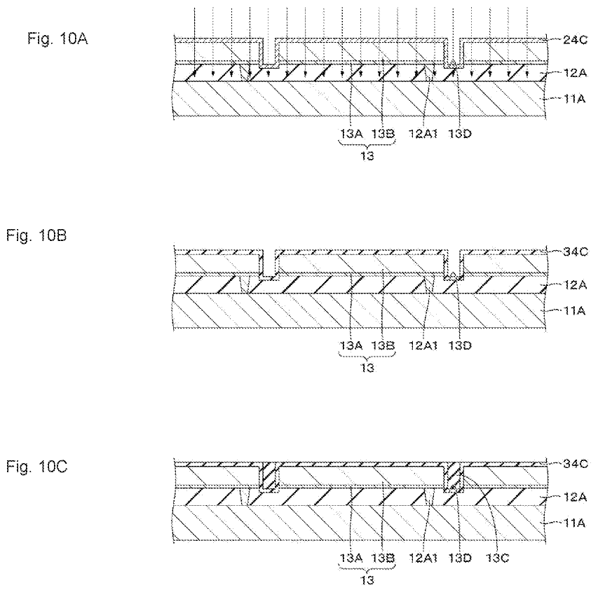

Next, ions are implanted into the transparent conductive oxide layer 24C (see FIG. 10A). As a result, the transparent conductive oxide layer 24C becomes highly resistant and becomes an insulating oxide layer 34C (see FIG. 10B). At least one selected from the group consisting of oxygen (O), sulfur (S) and nitrogen (N) is used as the first ion to be implanted.

Next, an insulating layer is formed in the grooves 13D between the adjacent reflective layers 13 and on the first surfaces of the plurality of reflective layers 13 by, for example, the CVD method. Next, the insulating layer formed on the first surface of each reflective layer 13 is removed by, for example, an etch-back method or a CMP method. As a result, an insulating portion 13C is formed in the grooves 13D between the adjacent reflective layers 13 (see FIG. 10C).

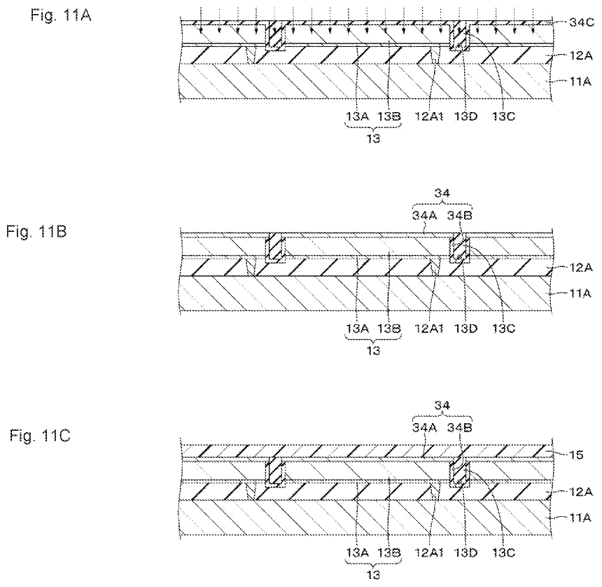

Next, ions are implanted into the first surface of the laminate obtained as described above (the surface on which the insulating oxide layer 34C and the insulating portion 13C are formed) (see FIG. 11A). As a result, ions are implanted into the first portion of the insulating oxide layer 34C covering the first surface of each first electrode 34A, and the first portion becomes less resistant and becomes a transparent conductive oxide layer. On the other hand, ions are not implanted into the second portion of the insulating oxide layer 34C provided in the groove 13D, and the second portion remains unchanged from the insulating oxide layer 34C. Accordingly, an oxide layer 34 including a plurality of first electrodes 34A and an isolating portion 34B is formed (see FIG. 11B). At least one selected from the group consisting of hydrogen (H), lithium (Li), magnesium (Mg) and cesium (Cs) is used as the second ion to be implanted.

Next, the organic layer 15 is formed by laminating a hole injection layer, a hole transport layer, a light-emitting layer, and an electron transport layer in this order on the first surface of the oxide layer 34 by vapor deposition, for example (see FIG. 11C).

Subsequent steps are performed in the same manner as in the manufacturing method of the display device 10 of the first embodiment. As described above, the display device 30 shown in FIG. 9 is obtained.

### Operation and Effect

As described above, the display device 30 according to the third embodiment includes the oxide layer 34, and the oxide layer 34 includes the plurality of first electrodes 14A and the isolating portion 34B. Therefore, the same effect as the display device 10 according to the first embodiment can be obtained.

### 4 MODIFICATION EXAMPLES

### Modification Example 1

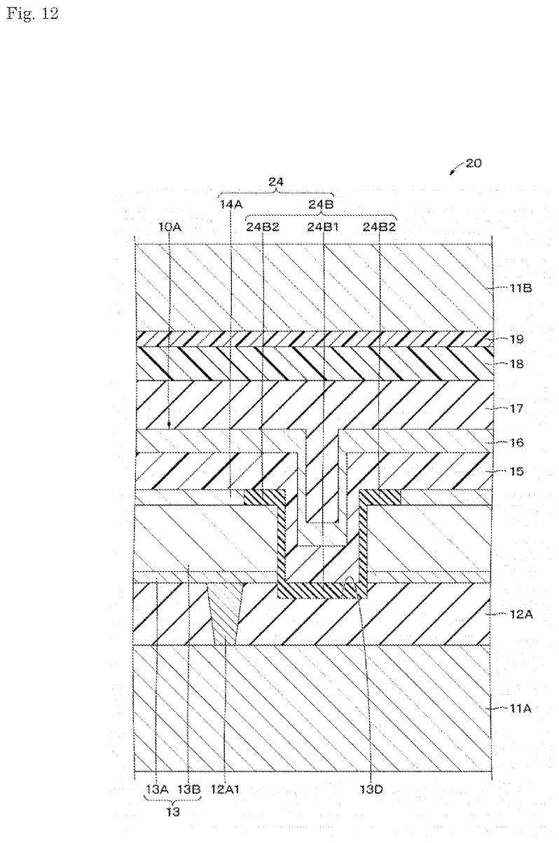

In the second embodiment, an example (see FIG. 6) in which the insulating portion 13C is provided in the recess 24B1 of the oxide layer 24 has been described, but as shown in FIG. 12, the insulating portion 13C may not be provided in the recess 24B1. In this case, the organic layer 15 and the second electrode 16 may be provided so as to follow the shape of the recess 24B1, and the protective layer 17 may fill the recess 24B1. Alternatively, the organic layer 15 may be provided so as to follow the shape of the recess 24B1, and the second electrode 16 may fill the recess 24B1.

Similarly, in the third embodiment, the insulating portion 13C may not be provided in the isolating portion 34B, which is a recess. In this case, the organic layer 15 and the second electrode 16 may be provided so as to follow the shape of the isolating portion 34B, and the protective layer 17 may fill the isolating portion 34B. Alternatively, the organic layer 15 may be provided so as to follow the shape of the isolating portion 34B, and the second electrode 16 may fill the isolating portion 34B.

### Modification Example 2

In the first to third embodiments, an example in which the present disclosure is applied to a display device has been described, but the present disclosure is not limited to this, and can be applied to light-emitting devices other than display devices. Examples of light-emitting devices other than display devices include, but are not limited to, lighting devices. In this case, the number of light-emitting elements included in the light-emitting device such as the lighting device may be plural or singular.

### 5 APPLICATION EXAMPLE

### Electronic Apparatus

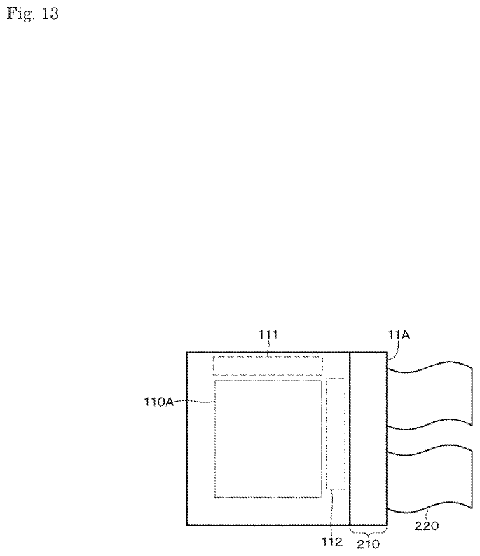

The display devices 10, 20, and 30 according to the above-described first to third embodiments and modification examples thereof can be used in various electronic apparatuses. The display devices 10, 20 and 30 are incorporated into various electronic apparatuses as modules as shown in FIG. 13, for example. In particular, the display devices are suitable for electronic viewfinders of video cameras or single-lens reflex cameras, head-mounted displays, or the like, which require high resolution and are used in close proximity to the eyes. This module has an exposed region 210 that is not covered with the counter substrate 11B or the like on one short side of the driving substrate 11A, and wiring of the signal line driving circuit 111 and the scanning line driving circuit 112 is extended so that an external connection terminal (not shown) is formed in this region 210. A flexible printed circuit (FPC) 220 for signal input/output may be connected to the external connection terminal.

### Specific Example 1

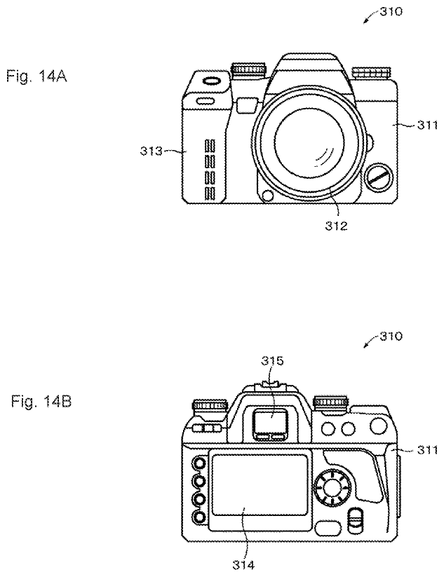

FIGS. 14A and 14B show an example of the appearance of a digital still camera 310. This digital still camera 310 is an interchangeable single-lens reflex-type camera, and has an interchangeable photographing lens unit (interchangeable lens) 312 in approximately the center of the front surface of a camera main body (camera body) 311, and has a grip portion 313 for a photographer to hold on the left side of the front surface.

A monitor 314 is provided at a position shifted to the left from the center of the rear surface of the camera body 311. An electronic viewfinder (eyepiece window) 315 is provided above the monitor 314. By looking through the electronic viewfinder 315, the photographer can view the optical image of a subject guided from the photographing lens unit 312 and determine the composition. As the electronic viewfinder 315, any one of the display devices 10, 20, and 30 can be used.

### Specific Example 2

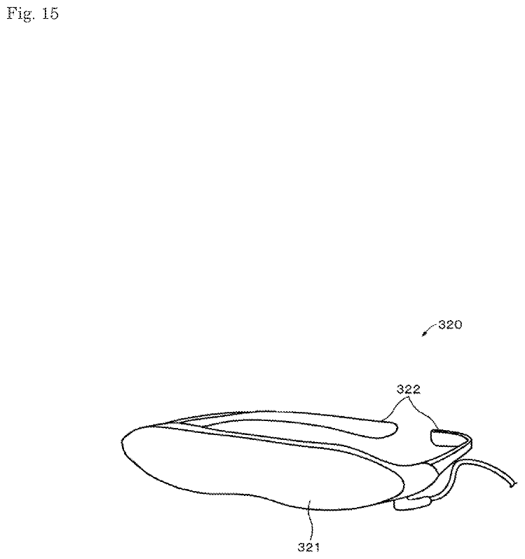

FIG. 15 shows an example of the appearance of a head-mounted display 320. The head-mounted display 320 has, for example, ear hooks 322 on both sides of an eyeglass-shaped display unit 321 to be worn on the user's head. As the display unit 321, any one of the display devices 10, 20, and 30 can be used.

### Specific Example 3

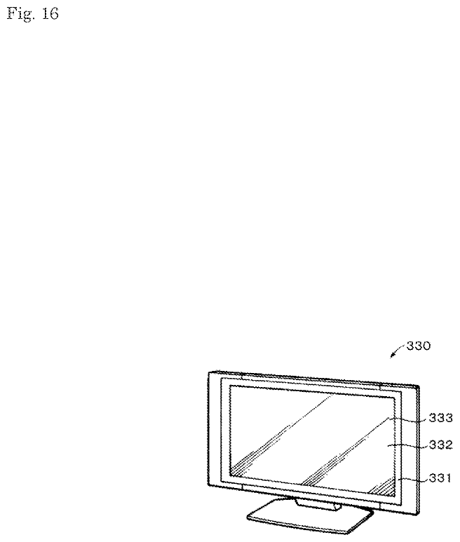

FIG. 16 shows an example of the appearance of a television device 330. This television device 330 has, for example, a video display screen portion 331 including a front panel 332 and a filter glass 333. The video display screen portion 331 is configured by any one of the display devices 10, 20, and 30.

Although the first to third embodiments of the present disclosure and the modification examples thereof have been specifically described above, the present disclosure is not limited to the above-described first to third embodiments and the modification examples thereof, and various modifications based on the technical idea of the present disclosure are possible.

For example, the configurations, methods, processes, shapes, materials, numerical values, and the like given in the above-described first to third embodiments and the modification examples thereof are merely examples, and different configurations, methods, processes, shapes, materials, numerical values, and the like may be used, if necessary.

In addition, the configurations, methods, processes, shapes, materials, numerical values, and the like in the first to third embodiments and the modification examples thereof described above can be combined with each other without departing from the gist of the present disclosure.

The materials exemplified in the above-described first to third embodiments and the modification examples thereof may be used singly or in combination of two or more unless otherwise specified.

In addition, the present disclosure may have the following constitutions.

(1)

A display device comprising: an oxide layer including a plurality of first electrodes and an isolating portion that electrically isolates adjacent first electrodes;
a second electrode facing one surface of the oxide layer; and
an organic light-emitting layer provided between the oxide layer and the second electrode.
   (2)

The display device according to (1), further comprising a plurality of reflective layers facing the other surface of the oxide layer), wherein
each of the plurality of reflective layers faces the plurality of first electrodes.
   (3)

The display device according to (2), wherein each of the plurality of reflective layers is adjacent to the plurality of first electrodes.

(4)

The display device according to (2) or (3), wherein the reflective layer has a main surface facing the organic light-emitting layer with the first electrode interposed therebetween,
the isolating portion has a recess concave with respect to the main surface, and a groove is provided between adjacent reflective layers, and the recess is provided in the groove.
   (5)

The display device according to (4), wherein the isolating portion further has a covering portion that covers a peripheral portion of the main surface.

(6)

The display device according to (4) or (5), wherein the groove has a depth equal to or greater than a thickness of the reflective layer.

(7)

The display device according to any one of (4) to (6), further comprising an insulating portion provided within the recess.

(8)

The display device according to any one of (4) to (6), wherein the organic light-emitting layer follows the recess.

(9)

The display device according to (2), further comprising an insulating layer provided between the oxide layer and the plurality of reflective layers.

(10)

The display device according to any one of (1) to (9), wherein an electrical resistance of the isolating portion is higher than an electrical resistance of the first electrode.

(11)

The display device according to any one of (1) to (10), wherein the isolating portion is an insulating portion.

(12)

The display device according to any one of (1) to (11), wherein the first electrode contains a transparent conductive oxide.

(13)

The display device according to (12), wherein the transparent conductive oxide contains at least one selected from the group consisting of a transparent conductive oxide containing indium, a transparent conductive oxide containing tin, and a transparent conductive oxide containing zinc.

(14)

The display device according to any one of (1) to (13), wherein the first electrode is a transparent electrode.

(15)

The display device according to any one of (1) to (11), wherein the first electrode contains a transparent conductive oxide, and
the isolating portion contains an insulating oxide.
   (16)

The display device according to any one of (1) to (11), wherein the first electrode contains a first oxide, and
the isolating portion contains a second oxide obtained by adding an impurity to the first oxide.
   (17)

The display device according to any one of (1) to (11), wherein the first electrode contains a first oxide,
the isolating portion contains a second oxide, and
the first oxide and the second oxide have different composition ratios.
   (18)

The display device according to any one of (1) to (17), wherein crystallinity of the first electrode is higher than crystallinity of the isolating portion.

(19)

A light-emitting device comprising: an oxide layer including a plurality of first electrodes and an isolating portion that electrically isolates adjacent first electrodes;
a second electrode facing the oxide layer; and
an organic light-emitting layer provided between the oxide layer and the second electrode.
   (20)

An electronic apparatus comprising the display device according to any one of (1) to (19).

### REFERENCE SIGNS LIST

10, 20, 30 Display device (Light-emitting device)
10A Light-emitting element
11A Driving substrate
11B Counter substrate
12A First insulating layer
12A Second insulating layer
13 Reflective layer
13A First metal layer
13B Second metal layer
13C Insulating portion
13D Groove
14, 24, 34 Oxide layer
14A, 34A First electrode
14B, 24B, 34B Isolating portion
24B1 Recess
24B2 Covering portion
15 Organic layer
16 Second electrode
17 Protective layer
18 Color filter
19 Filling resin layer
100R, 100G, 100B Sub-pixel
110A Display region
110B Peripheral region
111 Signal line driving circuit
111A Signal line
112 Scanning line driving circuit
112A Scanning line
310 Digital still camera (Electronic apparatus)
320 Head-mounted display (Electronic apparatus)
330 Television device (Electronic apparatus)

1. A display device comprising:
an oxide layer including a plurality of first electrodes and an isolating portion that electrically isolates adjacent first electrodes;
a second electrode facing one surface of the oxide layer; and
an organic light-emitting layer provided between the oxide layer and the second electrode.

2. The display device according to claim 1, further comprising
a plurality of reflective layers facing the other surface of the oxide layer, wherein each of the plurality of reflective layers faces the plurality of first electrodes.

3. The display device according to claim 2, wherein each of the plurality of reflective layers is adjacent to the plurality of first electrodes.

4. The display device according to claim 2, wherein
the reflective layer has a main surface facing the organic light-emitting layer with the first electrode interposed therebetween,
the isolating portion has a recess concave with respect to the main surface, and
a groove is provided between adjacent reflective layers, and the recess is provided in the groove.

5. The display device according to claim 4, wherein the isolating portion further has a covering portion that covers a peripheral portion of the main surface.

6. The display device according to claim 4, wherein the groove has a depth equal to or greater than a thickness of the reflective layer.

7. The display device according to claim 4, further comprising an insulating portion provided within the recess.

8. The display device according to claim 4, wherein the organic light-emitting layer follows the recess.

9. The display device according to claim 2, further comprising an insulating layer provided between the oxide layer and the plurality of reflective layers.

10. The display device according to claim 1, wherein an electrical resistance of the isolating portion is higher than an electrical resistance of the first electrode.

11. The display device according to claim 1, wherein the isolating portion is an insulating portion.

12. The display device according to claim 1, wherein the first electrode contains a transparent conductive oxide.

13. The display device according to claim 12, wherein the transparent conductive oxide contains at least one selected from the group consisting of a transparent conductive oxide containing indium, a transparent conductive oxide containing tin, and a transparent conductive oxide containing zinc.

14. The display device according to claim 1, wherein the first electrode is a transparent electrode.

15. The display device according to claim 1, wherein
the first electrode contains a transparent conductive oxide, and
the isolating portion contains an insulating oxide.

16. The display device according to claim 1, wherein
the first electrode contains a first oxide, and
the isolating portion contains a second oxide obtained by adding an impurity to the first oxide.

17. The display device according to claim 1, wherein
the first electrode contains a first oxide,
the isolating portion contains a second oxide, and
the first oxide and the second oxide have different composition ratios.

18. The display device according to claim 1, wherein crystallinity of the first electrode is higher than crystallinity of the isolating portion.

19. A light-emitting device comprising:
an oxide layer including a plurality of first electrodes and an isolating portion that electrically isolates adjacent first electrodes;
a second electrode facing the oxide layer; and
an organic light-emitting layer provided between the oxide layer and the second electrode.

20. An electronic apparatus comprising the display device according to claim 1.
